(19) United States
(12) Patent Application Publication
(10) Pub. No.: US 2025/0031485 A1
(43) Pub. Date: Jan. 23, 2025

(54) METHOD FOR MANUFACTURING LIGHT EMITTING DEVICE

(71) Applicant: NICHIA CORPORATION, Anan-shi (JP)

(72) Inventor: Yoshiki MATSUSHITA, Tokushima-shi (JP)

(73) Assignee: NICHIA CORPORATION, Anan-shi (JP)

(21) Appl. No.: 18/774,285

(22) Filed: Jul. 16, 2024

(30) Foreign Application Priority Data
Jul. 21, 2023 (JP) 2023-118832

(51) Int. Cl. H01L 33/00

(52) U.S. Cl. CPC H01L 33/0095; H01L 2933/0025; H01L 2933/0041

(57) ABSTRACT

A method for manufacturing a light-emitting device includes preparing a wafer in which multiple semiconductor parts are arranged on a first surface of a first substrate, disposing a resin member covering the first surface and the multiple semiconductor parts, disposing a second substrate on the resin member, removing the first substrate, forming a dielectric layer continuously covering upper surfaces of the multiple semiconductor parts and an upper surface of the resin member, causing an upper surface of the dielectric layer to approach flat, selectively removing the dielectric layer located on the upper surface of the resin member, and directly bonding a wavelength conversion member to the upper surface of the dielectric layer.

### CROSS-REFERENCE TO RELATED APPLICATIONS

This application is based upon and claims priority to Japanese Patent Application No. 2023-118832, filed on Jul. 21, 2023, the entire contents of which are incorporated herein by reference.

### FIELD

Embodiments of the invention described herein relate to a method for manufacturing a light-emitting device.

### BACKGROUND

There is a method for manufacturing a light-emitting device in which multiple semiconductor parts, each including a light-emitting part, are arranged in a substrate to be separated from each other, and a wavelength conversion member is bonded to the multiple semiconductor parts in the arranged state to bridge across the multiple semiconductor parts (see, e.g., PCT Publication No. WO2020/157811).

In such a method for manufacturing a light-emitting device, it is desirable to bond the wavelength conversion member to the dielectric layer located at the upper surface of the semiconductor part with high bonding strength.

### SUMMARY

An embodiment of the invention provides a method for manufacturing a light-emitting device in which a wavelength conversion member is bonded with a high bonding strength to a dielectric layer formed at an upper surface of a semiconductor part.

According to an aspect of the invention, a method for manufacturing a light-emitting device includes: a step of preparing a wafer including a first substrate and multiple semiconductor parts, the first substrate including a first surface, the multiple semiconductor parts being arranged on the first surface to be separated from each other, each of the multiple semiconductor parts including a light-emitting part; a step of disposing a resin member that covers the multiple semiconductor parts and the first surface positioned between the multiple semiconductor parts; a step of disposing a second substrate on the resin member; a step of exposing the portions of the multiple semiconductor parts and a portion of the resin member by removing the first substrate; a step of forming a dielectric layer continuously covering the portions of the multiple semiconductor parts and the portion of the resin member; a step of causing an upper surface of the dielectric layer to approach flat; a step of selectively removing the dielectric layer located on the portion of the resin member; and a step of directly bonding a wavelength conversion member to the upper surface of the dielectric layer caused to approach flat, the wavelength conversion member covering the multiple semiconductor parts.

### BRIEF DESCRIPTION OF THE DRAWINGS

FIG. 1 is a schematic cross-sectional view illustrating a step of a method for manufacturing a light-emitting device according to a first embodiment;

FIG. 2 is a schematic cross-sectional view illustrating a step of the method for manufacturing the light-emitting device according to the first embodiment;

FIG. 3 is a schematic cross-sectional view illustrating a step of the method for manufacturing the light-emitting device according to the first embodiment;

FIG. 4 is a schematic cross-sectional view illustrating a step of the method for manufacturing the light-emitting device according to the first embodiment;

FIG. 5 is a schematic plan view illustrating a step of the method for manufacturing the light-emitting device according to the first embodiment;

FIG. 6 is a schematic cross-sectional view illustrating a step of the method for manufacturing the light-emitting device according to the first embodiment;

FIG. 7 is a schematic cross-sectional view illustrating a step of the method for manufacturing the light-emitting device according to the first embodiment;

FIG. 8A is a schematic cross-sectional view illustrating a step of a modification of the method for manufacturing the light-emitting device according to the first embodiment;

FIG. 8B is a schematic cross-sectional view illustrating a step of another modification of the method for manufacturing the light-emitting device according to the first embodiment;

FIG. 9 is a schematic cross-sectional view illustrating a step of the method for manufacturing the light-emitting device according to the first embodiment;

FIG. 10 is a schematic cross-sectional view illustrating a step of the method for manufacturing the light-emitting device according to the first embodiment;

FIG. 11 is a schematic cross-sectional view illustrating a step of the method for manufacturing the light-emitting device according to the first embodiment;

FIG. 12 is a schematic cross-sectional view illustrating a step of a method for manufacturing a light-emitting device according to a second embodiment;

FIG. 13 is a schematic cross-sectional view illustrating a step of the method for manufacturing the light-emitting device according to the second embodiment; and

FIG. 14 is a schematic cross-sectional view illustrating a step of the method for manufacturing the light-emitting device according to the second embodiment.

### DETAILED DESCRIPTION

Embodiments of the invention will now be described with reference to the drawings.

The drawings are schematic or conceptual, and the relationships between the thickness and width of portions, the proportions of sizes among portions, etc., are not necessarily the same as the actual values. The dimensions and proportions may be illustrated differently among drawings, even when the same portion is illustrated.

In the specification and drawings, components similar to those described previously or illustrated in an antecedent drawing are marked with the same reference numerals, and a detailed description is omitted as appropriate.

### First Embodiment

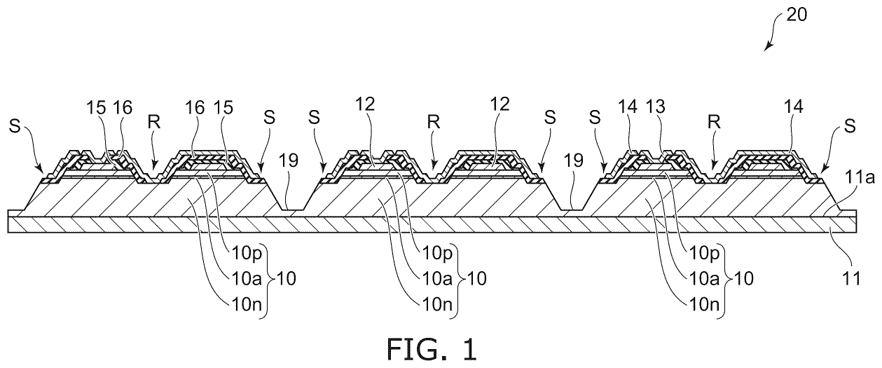

FIG. 1 is a schematic cross-sectional view illustrating a step of a method for manufacturing a light-emitting device according to a first embodiment.

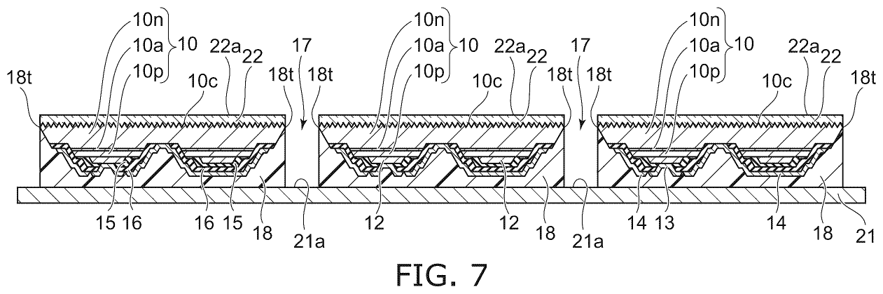

First, a wafer 20 is prepared as shown in FIG. 1. The wafer 20 includes a substrate (a first substrate) 11 and multiple semiconductor parts 10. The substrate 11 includes a first surface 11a. The multiple semiconductor parts 10 are arranged on the first surface 11a to be separated from each other. In the following description, the length in a direction orthogonal to the first surface 11a or a surface 21a of a support substrate 21 toward the semiconductor part 10 may be called the height or the thickness. The surface 21a of the support substrate 21 is described below with reference to FIG. 7.

The multiple semiconductor parts 10 each include a first semiconductor part 10n, a light-emitting part 10a, and a second semiconductor part 10p. The light-emitting part 10a is positioned between the first semiconductor part 10n and the second semiconductor part 10p. According to the embodiment, the first semiconductor part 10n includes an n-type semiconductor, and the second semiconductor part 10p includes a p-type semiconductor. The light-emitting part 10a includes multiple barrier layers and multiple well layers, and can have a multi-quantum well structure in which the barrier layers and the well layers are alternately stacked. For example, the multiple semiconductor parts 10 are formed as follows. Specifically, a semiconductor structure body that includes the first semiconductor part 10n, the light-emitting part 10a, and the second semiconductor part 10p is stacked on the substrate 11, and then a resist mask is formed on the regions of the semiconductor structure body at which the multiple semiconductor parts 10 will be formed. Subsequently, the multiple semiconductor parts 10 can be formed by removing a portion of the semiconductor structure body by using the resist mask. For example, RIE (Reactive Ion Etching) can be used to remove the semiconductor structure body.

The semiconductor part 10 is made of a nitride semiconductor layer. The nitride semiconductor includes all of the compositions of semiconductors of the chemical formula InₓAl_{y}Ga_{1-x-y}N (0≤x≤1, 0≤y≤1, and x+y≤1) for which the composition ratios x and y are changed within the ranges respectively. The first semiconductor part 10n includes a nitride semiconductor layer including Al and Ga, and includes, for example, an AlGaN layer.

For example, the semiconductor part 10 is formed by MOCVD (Metal Organic Chemical Vapor Deposition). The semiconductor part 10 is formed in the order of the first semiconductor part 10n, the light-emitting part 10a, and the second semiconductor part 10p on the first surface 11a.

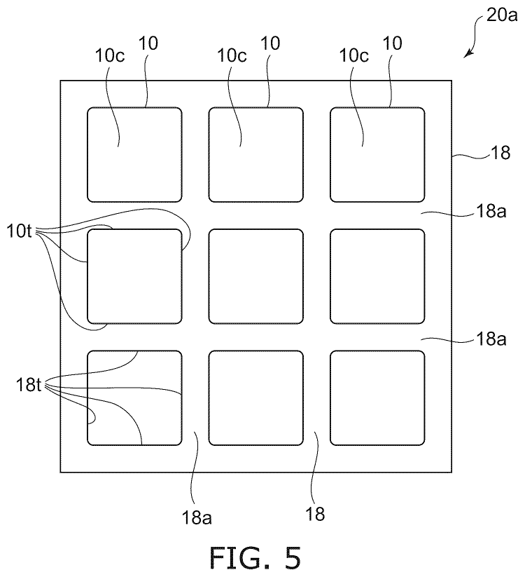

The semiconductor parts 10 are arranged in a matrix configuration on the first surface 11a in a plan view as described below with reference to FIG. 5. In the specific example shown in FIG. 1, the adjacent semiconductor parts 10 are connected to each other via a connection part 19. Similarly to the semiconductor part 10, the connection part 19 is located at the first surface 11a. The connection part 19 is continuous with the first semiconductor part 10n, and is formed of a semiconductor layer including the n-type semiconductor. The connection part 19 may not be formed.

The semiconductor part 10 includes a recess R. For example, the recess R is positioned at the central portion vicinity of the semiconductor part 10 in a plan view. The inner surface of the recess R includes the side surface of the first semiconductor part 10n, the side surface of the light-emitting part 10a, and the side surface of the second semiconductor part 10p, and the bottom surface of the recess R is formed of the first semiconductor part 10n. The inner surface of the recess R is an oblique surface that is oblique to the first surface 11a. For example, the recess R can be formed by forming a resist mask on the regions of the semiconductor part 10 other than the regions that will become the recesses R, and then by removing a portion of the semiconductor part by using the resist mask. For example, RIE can be used to remove the semiconductor part. By forming the recess R by removing the semiconductor part with RIE, the inner surface of the recess R becomes an oblique surface that is oblique to the first surface 11a.

The first semiconductor part 10n includes an exposed portion S that is not covered by the second semiconductor part 10p or the light-emitting part 10a. The height from the first surface 11a to the exposed portion S is substantially equal to the height from the first surface 11a to the bottom surface of the recess R. The exposed portion S is located at the periphery of the first semiconductor part 10n. The exposed portion S can be formed in the same step as the step of forming the recess R described above. For example, the exposed portion S can be formed by forming a resist mask on the regions of the semiconductor part 10 other than the regions that will become the recess R and the regions that will become the exposed portion S, and then by removing a portion of the semiconductor part by using the resist mask. The semiconductor structure body may be stacked on the substrate 11, subsequently the recess R and the exposed portion S for each region that will become the semiconductor part 10 may be formed, and then the semiconductor structure body may be divided into the multiple semiconductor parts 10.

The semiconductor part 10 from the first surface 11a to the exposed portion S is formed of the first semiconductor part 10n. The side surface of the first semiconductor part 10n is an oblique surface that is oblique to the first surface 11a. The semiconductor part 10 includes a stacked body that is positioned on the first semiconductor part 10n and includes the light-emitting part 10a and the second semiconductor part 10p. The side surface of the stacked body is an oblique surface that is oblique to the first surface 11a.

A light-reflective electrode 12 is located on the second semiconductor part 10p. The light-reflective electrode 12 is electrically connected to the second semiconductor part 10p. The light-reflective electrode 12 increases light extraction efficiency by reflecting, toward the first semiconductor part 10n side, the light traveling from the light-emitting part 10a toward the second semiconductor part 10p side. It is favorable for the light-reflective electrode 12 to include a metal material having high light reflectivity. It is favorable for the light-reflective electrode 12 to have a reflectance of not less than 60%, and favorably not less than 70%, for light of the peak wavelength emitted by the light-emitting part 10a. A metal material such as Ag, Al, Rh, Ni, Ti, Pt, or the like, an alloy having such a metal material as a major component, etc., can be used as the metal material of the light-reflective electrode 12. The light-reflective electrode 12 may have a single-layer structure of a layer made of these metal materials, or may have a stacked structure in which multiple layers are stacked. For example, the light-reflective electrode 12 can be formed by sputtering, vapor deposition, etc.

A first insulating film 15 is located on the second semiconductor part 10p and on the light-reflective electrode 12. The first insulating film 15 has an opening exposing a portion of the light-reflective electrode 12. For example, the first insulating film 15 is a silicon oxide film or a silicon nitride film. For example, the first insulating film 15 can be formed by sputtering and/or vapor deposition. After the first insulating film 15 is formed, an opening can be formed in the first insulating film 15 by removing a portion of the first insulating film 15. For example, the opening can be formed by removing the first insulating film 15 by wet etching, dry etching, etc.

A second insulating film 16 is located on the side surface of the second semiconductor part 10p, on the side surface of the light-emitting part 10a, and on the first insulating film 15. The second insulating film 16 is located on the exposed portion S and the side surface of the first semiconductor part 10n. The second insulating film 16 has an opening that exposes a portion of the light-reflective electrode 12, and an opening that exposes a portion of the bottom surface of the recess R. The second insulating film 16 is, for example, a silicon oxide film or a silicon nitride film. For example, the second insulating film 16 can be formed by sputtering and/or vapor deposition. After the second insulating film 16 is formed, an opening can be formed in the second insulating film 16 by removing a portion of the second insulating film 16. For example, the opening can be formed by removing the second insulating film 16 by wet etching, dry etching, etc.

A first conductive member 14 is located on the second insulating film 16. The first conductive member 14 is electrically connected to the first semiconductor part 10n via the opening of the second insulating film 16 that exposes a portion of the bottom surface of the recess R. For example, the first conductive member 14 can be formed by sputtering, vapor deposition, etc.

A second conductive member 13 is located on the second insulating film 16. The second conductive member 13 is electrically connected to the light-reflective electrode 12 via the opening of the first insulating film 15 and the opening of the second insulating film 16. The second conductive member 13 is electrically connected to the second semiconductor part 10p via the light-reflective electrode 12. For example, the second conductive member 13 can be formed by sputtering, vapor deposition, etc.

A metal material such as Al, Rh, Ag, Ti, Pt, Au, Cu, Si, or the like, a semiconductor material, or an alloy having such materials as a major component can be used as the materials of the first and second conductive members 14 and 13. The first conductive member 14 and the second conductive member 13 may have a single-layer structure of a layer made of these metal materials, or may have a stacked structure in which multiple layers are stacked. The first conductive member 14 and the second conductive member 13 may have the same structure of the same materials, or may have different structures of different materials.

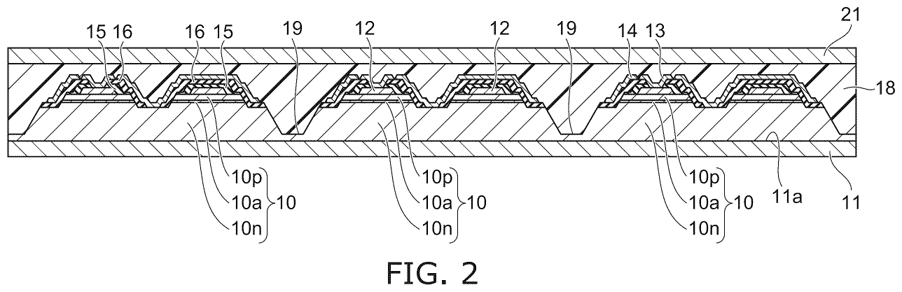

FIG. 2 is a schematic cross-sectional view illustrating a step of a method for manufacturing the light-emitting device according to the first embodiment.

As shown in FIG. 2, a resin member 18 is disposed on the wafer 20. For example, this step is performed by disposing the resin member 18 on the support substrate 21, and then bonding the wafer 20 and the support substrate 21 via the resin member 18 in a state in which the resin member 18 is positioned between the substrate 11 and the support substrate 21. The resin member 18 is formed by such a step to cover the side surface of the semiconductor part 10, the second insulating film 16, the first conductive member 14, and the second conductive member 13. The resin member 18 also is located between the two adjacent semiconductor parts 10. That is, the resin member 18 is located on the first surface 11a of the substrate 11. In the example of FIG. 2, the resin member 18 is located on the first surface 11a with the connection part 19 interposed. When the connection part 19 is not provided, the resin member 18 is located in contact with the first surface 11a of the substrate 11. The resin member 18 can include, for example, an epoxy resin, an acrylic resin, a polyimide resin, etc.

A support substrate (a second substrate) 21 is disposed on the resin member 18, and the support substrate 21 is bonded with the resin member 18. The support substrate 21 can include, for example, a sapphire substrate, or a silicon substrate, etc.

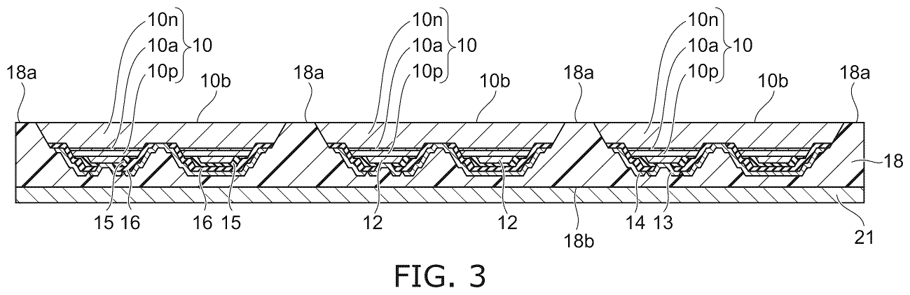

FIG. 3 is a schematic cross-sectional view illustrating a step of the method for manufacturing the light-emitting device according to the first embodiment.

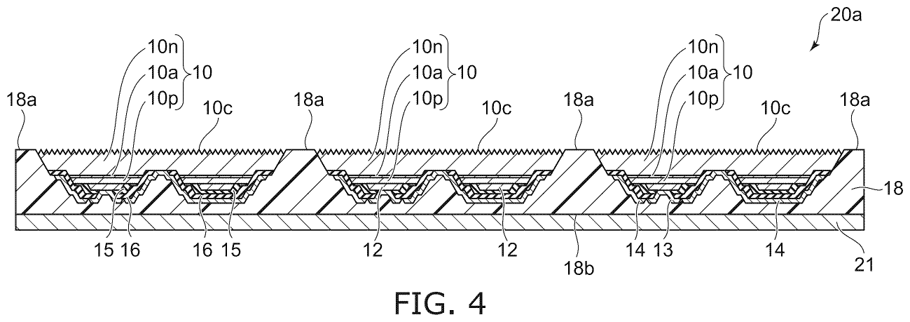

The display in FIG. 3 is vertically inverted with respect to the display of FIGS. 1 and 2. The semiconductor parts 10 are located under the support substrate 21 in FIGS. 1 and 2, while the semiconductor parts 10 are located on the support substrate 21 in FIG. 3. The displays of FIGS. 4 and 6 to FIG. 14 below are similarly inverted vertically with respect to FIGS. 1 and 2.

After the substrate 11 is removed from the wafer 20 including the resin member 18 and the support substrate 21 as shown in FIG. 3, a portion of the semiconductor parts 10 and a portion of the resin member 18 are exposed by removing a portion of the semiconductor parts 10. According to the embodiment, the connection part 19 shown in FIGS. 1 and 2 is removed after removing the substrate 11.

A method such as LLO (Laser Lift Off), grinding, polishing, etching, or the like is used to remove the substrate 11. When the substrate 11 is a sapphire substrate, it is favorable to remove the substrate 11 by LLO. The exposed surface of the semiconductor part 10 exposed by removing the substrate 11 is called a semiconductor upper surface 10b. The exposed surface of the resin member 18 exposed by removing the semiconductor part 10 is called a resin upper surface 18a, and the surface positioned at the side opposite to the resin upper surface 18a is called a resin lower surface 18b.

FIG. 4 is a schematic cross-sectional view illustrating a step of the method for manufacturing the light-emitting device according to the first embodiment.

The semiconductor upper surface 10b is roughened as shown in FIG. 4. This roughening step forms an intermediate member 20a including the semiconductor part 10 having a roughened semiconductor upper surface 10c. The light extraction efficiency of the light-emitting device can be increased by roughening the semiconductor upper surface 10b, which is a major light extraction surface, and by using the semiconductor upper surface 10b as the semiconductor upper surface 10c. For example, RIE using a gas including chlorine and/or wet etching using an alkaline solution such as TMAH (Tetramethyl Ammonium Hydroxide) or the like can be used to roughen the semiconductor upper surface 10b. By performing the roughening step, the height from the resin lower surface 18b to the semiconductor upper surface 10b becomes less than the height from the resin lower surface 18b to the resin upper surface 18a. The arithmetic average roughness Ra of the semiconductor upper surface 10b before performing the roughening step is, for example, not less than 0.1 nm and not more than 0.5 nm. The arithmetic average roughness Ra of the semiconductor upper surface 10b after performing the roughening step is, for example, not less than 100 nm and not more than 250 nm.

Although it is favorable to roughen the semiconductor upper surface 10b as described above, the semiconductor upper surface 10b need not be roughened. The manufacturing steps of the light-emitting device can be reduced by omitting the roughening of the semiconductor upper surface 10b.

FIG. 5 is a schematic plan view illustrating a step of the method for manufacturing the light-emitting device according to the first embodiment. FIG. 5 shows the state after performing the step of roughening the semiconductor upper surface 10b described above.

The intermediate member 20a in which the roughened semiconductor upper surface 10c is exposed is shown in the plan view of FIG. 5. As shown in FIG. 5, the semiconductor parts 10 of which the semiconductor upper surfaces 10c are exposed are arranged in a matrix configuration. The resin member 18 is located between the adjacent semiconductor parts 10, and the resin upper surface 18a is not covered by the semiconductor parts 10.

In each of the multiple semiconductor parts 10, in a plan view, the portion of the semiconductor upper surface 10c that contacts the resin upper surface 18a of the resin member 18 is called an end portion 10t of the semiconductor upper surface 10c. In the example, the exterior shape of the end portion 10t is substantially rectangular. The portion of the resin upper surface 18a contacting the end portion 10t is called a resin end portion 18t. The end portion 10t of the semiconductor part 10 defines the outer perimeter shape of the semiconductor part 10 in a plan view.

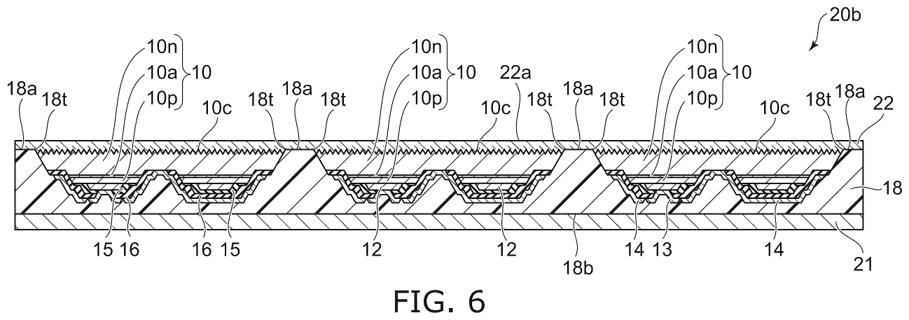

FIG. 6 is a schematic cross-sectional view illustrating a step of the method for manufacturing the light-emitting device according to the first embodiment.

As shown in FIG. 6, an intermediate member 20b is formed by forming a dielectric layer 22 that continuously covers a portion of the semiconductor part 10 and a portion of the resin member 18. The dielectric layer 22 is formed to cover the semiconductor upper surface 10c of the semiconductor part 10, the resin upper surface 18a of the resin member 18, and the side surface of the resin member 18 from the resin end portion 18t to the resin upper surface 18a. The thickness of the dielectric layer 22 is, for example, not less than 1 μm and not more than 50 μm. As a result, a sufficient arithmetic average roughness Ra can be ensured while reducing the time necessary for a step of causing the upper surface of the dielectric layer 22 to approach flat. FIG. 6 shows the state of the dielectric layer 22 after performing the step of causing the upper surface of the dielectric layer 22 to approach flat, which is described below. The arithmetic average roughness Ra of the upper surface of the dielectric layer 22 before performing the step of causing the upper surface of the dielectric layer 22 to approach flat is greater than the arithmetic average roughness Ra of the upper surface of the dielectric layer 22 after performing the step of causing the upper surface of the dielectric layer 22 to approach flat.

The dielectric layer 22 is a dielectric film of an inorganic material. The dielectric layer 22 is light-transmissive, and transmits the light emitted from the light-emitting part 10a of the semiconductor part 10. It is favorable for the dielectric layer 22 to have a transmittance of not less than 60%, and favorably not less than 70%, for the light of the peak wavelength emitted by the light-emitting part 10a. The dielectric layer 22 is a silicon oxide film, a silicon nitride film, a silicon oxynitride film, or an aluminum oxide film. For example, CVD (Chemical Vapor Deposition) or the like can be used to form the dielectric layer 22.

After forming the dielectric layer 22, the upper surface of the dielectric layer 22 is caused to approach flat. For example, chemical mechanical polishing (CMP) can be used as the method of causing the upper surface of the dielectric layer 22 to approach flat. The arithmetic average roughness Ra of the upper surface of the dielectric layer 22 before performing the step of causing the upper surface of the dielectric layer 22 to approach flat is, for example, not less than 50 nm and not more than 200 nm. The arithmetic average roughness Ra of the upper surface of the dielectric layer 22 after performing the step of causing the upper surface of the dielectric layer 22 to approach flat is, for example, not less than 0.1 nm and not more than 0.5 nm. In the specification, approaching flat means that the arithmetic average roughness Ra of the surface approaching flat approaches 0.

For example, the dielectric layer 22 can have an upper surface 22a that approaches flat by polishing about ⅓ of the formed thickness. For example, the upper surface 22a can approach flat by forming the dielectric layer 22 to have a thickness of about 10 μm, and then polishing about 3 μm of the 10 μm thickness. When the resin member 18 is formed of the epoxy resin, etc., described above and the dielectric layer 22 is formed of silicon oxide, etc., described above, the etching rate of the resin member 18 is less than the etching rate of the dielectric layer 22 in the polishing step by CMP.

FIG. 7 is a schematic cross-sectional view illustrating a step of the method for manufacturing the light-emitting device according to the first embodiment.

As shown in FIG. 7, a trench 17 is formed by selectively removing the dielectric layer 22 and the resin member 18 in the region between the two adjacent semiconductor parts 10 from the intermediate member 20b shown in FIG. 6. In the specific example of FIG. 7, the trench 17 is formed by removing the resin member 18 to expose the surface 21a of the support substrate 21. In such a case, the resin member 18 is divided for each semiconductor part 10 on the support substrate 21. As described above with reference to FIG. 2, the surface 21a of the support substrate 21 is the bonding surface with the resin member 18 of the support substrate 21 located on the resin member 18.

The trench 17 is formed along the resin end portion 18t of the resin member 18 shown in FIG. 5 in a plan view. More specifically, the trench 17 is formed by selectively removing the portion of the dielectric layer 22 corresponding to the region overlapping the resin end portions 18t, and then selectively removing the portion of the resin member 18 from the resin upper surface 18a to the resin lower surface 18b shown in FIG. 6 along the resin end portions 18t. For example, dry etching and/or wet etching is used to remove the resin member 18.

As described above with reference to FIG. 6, in the polishing by CMP, it is favorable for the etching rate of the resin member 18 to be less than the etching rate of the dielectric layer 22, and to stop the polishing amount of the dielectric layer 22 so that the resin member 18 is not exposed. According to the embodiment, even when the dielectric layer 22 is polished until the resin member 18 is exposed, the exposed portion of the resin member 18 is selectively removed by forming the trench 17. Therefore, the upper surface 22a of the dielectric layer 22 can sufficiently approach flat.

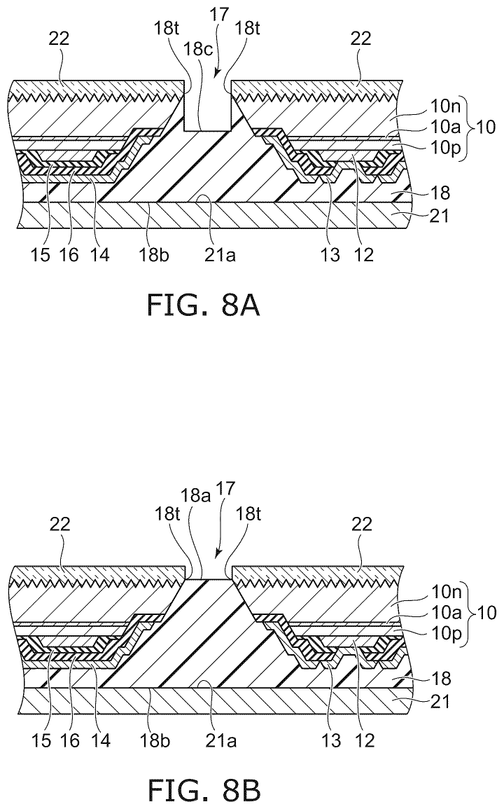

FIG. 8A is a schematic cross-sectional view illustrating a step of a modification of the method for manufacturing the light-emitting device according to the first embodiment.

FIG. 8B is a schematic cross-sectional view illustrating a step of another modification of the method for manufacturing the light-emitting device according to the first embodiment.

Although the trench 17 that exposes the surface 21a of the support substrate 21 is formed in the example shown in FIG. 7, the trench 17 may be formed not to expose the surface 21a of the support substrate 21 as in the modifications shown in FIGS. 8A and 8B. For example, such a trench 17 can be formed by appropriately adjusting the etching time when removing the resin member 18 by dry etching, wet etching, etc. As long as the portion of the intermediate member 20b corresponding to the region overlapping the resin end portions 18t in a plan view can be made about as thick or thinner than the other portions, the resin member 18 may not be removed until the surface 21a of the support substrate 21 is exposed. As shown in FIG. 8A, a portion of the resin member 18 may be removed up to partway through the resin member 18 in the height direction from the resin upper surface 18a toward the resin lower surface 18b. That is, the trench 17 that has a surface 18c of the resin member 18 as a bottom surface may be formed without exposing the surface 21a.

As shown in FIG. 8B, the trench 17 may be formed to have the resin upper surface 18a as the bottom surface by exposing the resin upper surface 18a by selectively removing the portion of the dielectric layer 22 corresponding to the region overlapping the resin end portions 18t in a plan view. For example, such a trench 17 can be formed by appropriately adjusting the etching time when removing the resin member 18 by dry etching, wet etching, etc.

As in these modifications, the processing time of the step of forming the trench 17 can be reduced by removing a portion of the resin member 18 or by not removing the resin member 18. By reducing the removal amount of the resin member 18 in this step, the resin member 18 residue can be prevented from adhering to the upper surface 22a of the dielectric layer 22. Therefore, the wavelength conversion member and the dielectric layer 22 can be bonded with a higher bonding strength in a subsequent step.

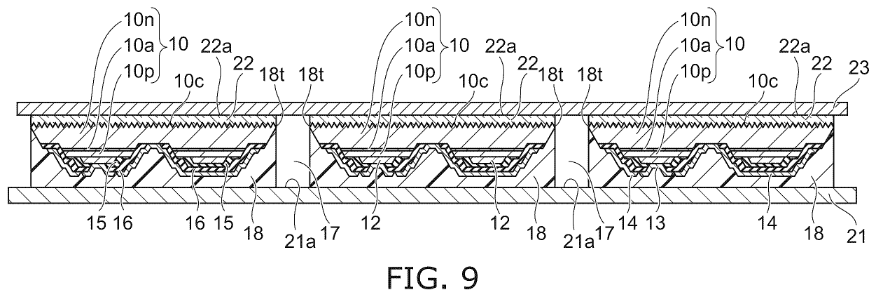

FIG. 9 is a schematic cross-sectional view illustrating a step of the method for manufacturing the light-emitting device according to the first embodiment.

As shown in FIG. 9, a wavelength conversion member 23 is disposed at the upper surface 22a of the dielectric layer 22 that approaches flat. The wavelength conversion member 23 is disposed to cover the multiple semiconductor parts 10 and the trench 17 between the adjacent semiconductor parts 10. The wavelength conversion member 23 is directly bonded to the upper surface 22a of the dielectric layer 22 that approaches flat.

For example, SAB (Surface Activated Bonding) can be used to directly bond the dielectric layer 22 and the wavelength conversion member 23. In SAB, the dielectric layer 22 and the wavelength conversion member 23 are directly bonded after using surface treatment to activate the bonding surface of the wavelength conversion member 23 and the upper surface 22a, which is the bonding surface of the dielectric layer 22. The method of activating the upper surface 22a of the dielectric layer 22 and the bonding surface of the wavelength conversion member 23 can include, for example, surface treatment of irradiating an ion beam including ions of Ar or the like on the bonding surfaces in a vacuum. By directly bonding the dielectric layer 22 and the wavelength conversion member 23, for example, compared to when an adhesive including a resin is used, the light extraction efficiency can be increased because there is no optical absorption by an adhesive. In direct bonding, a higher bonding strength can be obtained by applying a sufficient load between the upper surface 22a of the dielectric layer 22 and the bonding surface of the wavelength conversion member 23. It is favorable to perform direct bonding with low arithmetic average roughnesses Ra of the bonding surfaces, so that a sufficient load can be applied between the bonding surfaces to bond with a high bonding strength.

The wavelength conversion member 23 can include a sintered body formed of a phosphor contained in a binder made of a resin such as an epoxy resin, a silicone resin, etc. The sintered body of the phosphor refers to a member in which the phosphor is sintered together with a ceramic such as aluminum oxide, aluminum nitride, silicon nitride, silicon carbide, zirconium oxide, titanium oxide, etc., and the member does not include a resin. By using the sintered body of the phosphor as the wavelength conversion member 23, a reduction of the wavelength conversion efficiency can be suppressed because the heat dissipation of the phosphor is better than that of a phosphor included in a binder made of a resin. The phosphor can include an yttrium-aluminum-garnet-based phosphor (e.g., Y₃(Al, Ga)₅O₁₂:Ce), a lutetium-aluminum-garnet-based phosphor (e.g., Lu₃(Al, Ga)₅O₁₂:Ce), a terbium-aluminum-garnet-based phosphor (e.g., Tb₃(Al, Ga)₅O₁₂:Ce), a β-sialon-based phosphor (e.g., (Si, Al)₃(O, N)₄:Eu), an α-sialon-based phosphor (e.g., Ca(Si, Al)₁₂(O, N)₁₆:Eu), a nitride-based phosphor such as a CASN-based phosphor (e.g., CaAlSiN₃:Eu), a SCASN-based phosphor (e.g., (Sr, Ca) AISiN₃:Eu), or the like, a fluoride-based phosphor such as a KSF-based phosphor (e.g., K₂SiF₆:Mn), a KSAF-based phosphor (e.g., K₂(Si, Al)F₆:Mn), a MGF-based phosphor (e.g., 3.5MgO·0.5MgF₂·GeO₂:Mn), or the like, a phosphor having a perovskite structure (e.g., CsPb(F, Cl, Br, I)₃), or a quantum dot phosphor (e.g., CdSe, InP, AgInS₂, or AgInSe₂), etc. The thickness of the wavelength conversion member 23 is, for example, not less than 100 μm and not more than 500 μm, favorably not less than 120 μm and not more than 300 μm, and more favorably not less than 130 μm and not more than 260 μm.

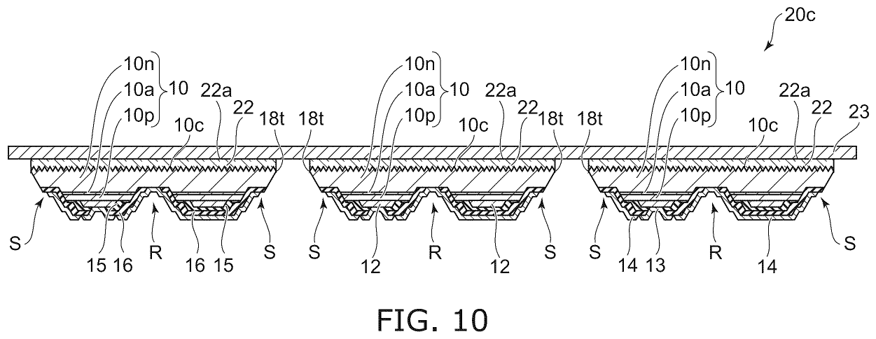

FIG. 10 is a schematic cross-sectional view illustrating a step of the method for manufacturing the light-emitting device according to the first embodiment.

As shown in FIG. 10, an intermediate member 20c in which the multiple semiconductor parts 10 are bonded to one wavelength conversion member 23 is formed by removing the support substrate 21 and the resin member 18 shown in FIG. 9. For example, LLO, wet etching, or the like is used to remove the support substrate 21. For example, wet etching or the like is used to remove the resin member 18.

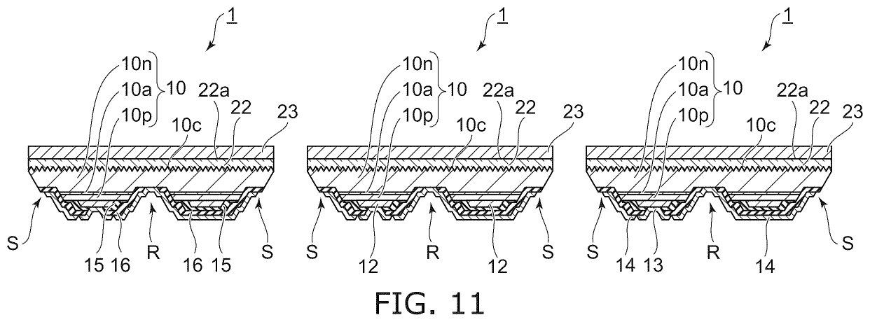

FIG. 11 is a schematic cross-sectional view illustrating a step of the method for manufacturing the light-emitting device according to the first embodiment.

As shown in FIG. 11, the wavelength conversion member 23 shown in FIG. 10 is cleaved at the positions of the intermediate member 20c between the multiple semiconductor parts 10 to singulate into the multiple light-emitting devices 1. For example, the cleaving locations of the wavelength conversion member 23 are positions corresponding to the trench 17 shown in FIG. 9. Blade dicing, laser scribing, or the like is used to cleave the wavelength conversion member 23. The multiple light-emitting devices 1 each include the semiconductor part 10 and the wavelength conversion member 23.

Effects of the method for manufacturing the light-emitting device 1 according to the embodiment will now be described.

According to the method for manufacturing the light-emitting device 1 according to the embodiment, the resin member 18 covers the multiple semiconductor parts 10 arranged to be separated from each other and the first surface 11a between two adjacent semiconductor parts 10, and then the wafer 20 and the support substrate 21 are bonded via the resin member 18. Therefore, the multiple semiconductor parts 10 that are arranged to be separated from each other can be stably bonded to the support substrate 21.

Subsequently, the substrate 11 is removed from the intermediate member including the multiple semiconductor parts 10 and the resin member 18 bonded to the support substrate 21, and the dielectric layer 22 that continuously covers the exposed semiconductor upper surfaces 10b and 10c and the exposed resin upper surface 18a is formed.

Subsequently, the upper surface 22a of the dielectric layer 22 is polished to approach flat by CMP, etc. When the dielectric layer 22 is formed to continuously cover the semiconductor part 10 and the resin member 18, there is a tendency for the arithmetic average roughness Ra of the upper surface 22a positioned on the semiconductor part 10 and the arithmetic average roughness Ra of the upper surface 22a positioned on the resin member 18 to be different when the step of polishing the upper surface 22a of the dielectric layer 22 is performed. It is estimated that this is because the different members positioned below the dielectric layer 22 cause fluctuation in the load applied to the upper surface 22a. When the wavelength conversion member 23 is directly bonded to the upper surface 22a of the dielectric layer 22 that has such surfaces of different arithmetic average roughnesses Ra, a sufficient load cannot be applied between the bonding surface of the wavelength conversion member 23 and the upper surface 22a, which is the bonding surface of the dielectric layer 22, and it is difficult to directly bond with a high bonding strength.

According to the method for manufacturing the light-emitting device 1 according to the embodiment, the dielectric layer 22 that overlaps the resin upper surface 18a in a plan view is selectively removed after the step of causing the upper surface 22a of the dielectric layer 22 to approach flat. Therefore, the arithmetic average roughness Ra difference due to the upper surface 22a of the dielectric layer 22 described above can be reduced.

Thus, because the upper surface 22a of the dielectric layer 22 can approach a flat state, a sufficient load can be applied between the bonding surface of the wavelength conversion member 23 and the upper surface 22a, which is the bonding surface of the dielectric layer 22, and so the wavelength conversion member 23 can be directly bonded to the dielectric layer 22 with a high bonding strength.

### Second Embodiment

According to the method for manufacturing the light-emitting device according to the first embodiment, the step of selectively removing the dielectric layer 22 that is positioned to overlap the trench 17 in a plan view is performed after performing the step of causing the upper surface 22a of the dielectric layer 22 to approach flat. The method for manufacturing the light-emitting device of the second embodiment differs from the manufacturing method of the first embodiment mainly in that the step of selectively removing the dielectric layer 22 is performed before the step of causing the upper surface 22a of the dielectric layer 22 to approach flat. In the second embodiment, the dielectric layer 22 is formed to continuously cover the roughened semiconductor upper surface 10c and the exposed portion of the resin member 18 after the step of roughening the semiconductor upper surface 10b described with reference to FIGS. 4 and 5. Similarly to the first embodiment, the step of roughening the semiconductor upper surface may not always be performed. When the step of roughening the semiconductor upper surface is not performed, the dielectric layer 22 is formed to continuously cover the semiconductor upper surface 10b and the resin upper surface 18a described with reference to FIG. 3.

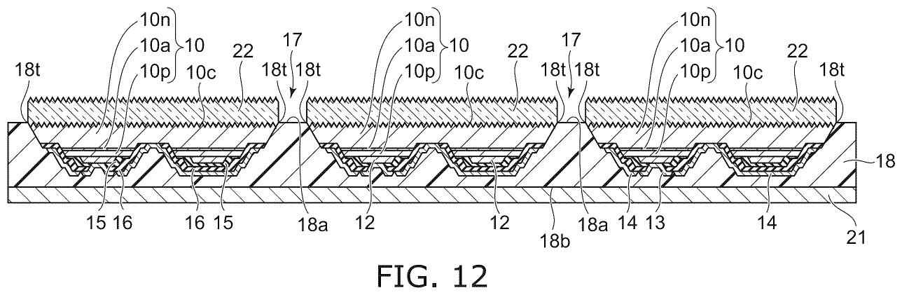

FIG. 12 is a schematic cross-sectional view illustrating a step of a method for manufacturing a light-emitting device according to the second embodiment.

The dielectric layer 22 is formed to continuously cover the semiconductor upper surfaces 10c of the intermediate member 20a and the portion of the resin member 18 surrounded with the resin end portions 18t shown in FIGS. 4 and 5. Subsequently, a resist mask that covers the regions of the dielectric layer 22 positioned on the semiconductor parts 10 is formed, and a portion of the dielectric layer 22 is selectively removed using the resist mask. This step thereby disposes the dielectric layer 22 on the semiconductor parts 10 as shown in FIG. 12. The portion of the dielectric layer 22 that is selectively removed corresponds to the regions overlapping the resin end portions 18t when in a plan view. In the specific example, similarly to the example shown in FIG. 8B, the trench 17 is formed by selectively removing the dielectric layer 22. The bottom surface of the trench 17 is the resin upper surface 18a. The trench 17 is not limited to the example above, and may be formed by further removing the resin member 18 selectively. The step of selectively removing the portion of the dielectric layer 22 does not include the step of causing the upper surface of the dielectric layer 22 to approach flat, and so the upper surface of the dielectric layer 22 shown in FIG. 12 is illustrated as a rough surface.

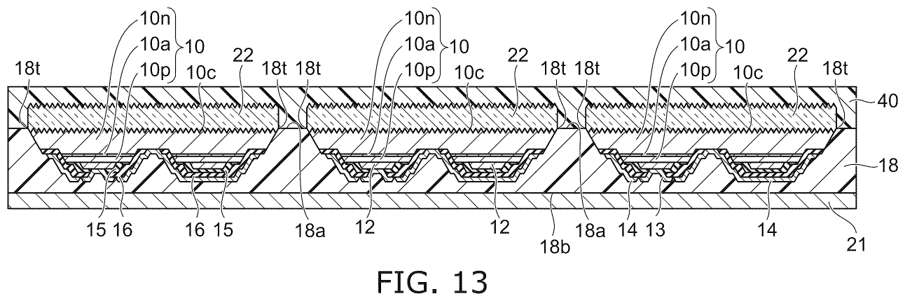

FIG. 13 is a schematic cross-sectional view illustrating a step of the method for manufacturing the light-emitting device according to the second embodiment.

As shown in FIG. 13, a covering member 40 that covers the top of the dielectric layer 22, the inner surface of the dielectric layer 22 exposed inside the trench 17, and the resin upper surface 18a is formed. The etching rate of the covering member 40 is greater than the etching rate of the dielectric layer 22 in the step of polishing the dielectric layer 22 and the covering member 40. For example, the covering member 40 is formed of a resin material.

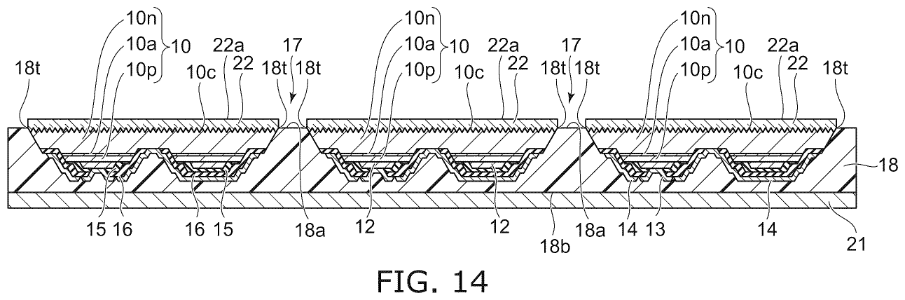

FIG. 14 is a schematic cross-sectional view illustrating a step of the method for manufacturing the light-emitting device according to the second embodiment.

As shown in FIG. 14, the upper surface 22a is formed by polishing the upper surface of the dielectric layer 22 to approach flat. In the example shown in FIG. 14, the entire covering member 40 is removed and the resin upper surface 18a is exposed because the covering member 40 has a higher etching rate than the dielectric layer 22.

Thereafter, as described with reference to FIGS. 9 to 11, the wavelength conversion member 23 is disposed on the dielectric layer 22, and the upper surface 22a of the dielectric layer 22 and the wavelength conversion member 23 are directly bonded. After the support substrate 21 and the resin member 18 are removed, the wavelength conversion member 23 is cleaved along the trench 17 to singulate into the multiple light-emitting devices 1.

Effects of the method for manufacturing the light-emitting device 1 according to the embodiment will now be described.

According to the embodiment, before performing the step of causing the upper surface 22a of the dielectric layer 22 to approach flat, at least a portion of the dielectric layer 22 is selectively removed along the resin end portions 18t, and the covering member 40 is formed to cover the dielectric layer 22 and fill the trench 17 that is formed. The covering member 40 is formed of a material having a higher etching rate than the dielectric layer 22 in the step of performing chemical mechanical polishing of the dielectric layer 22 and the covering member 40. Therefore, when polishing the covering member 40 and the dielectric layer 22, the covering member 40 is etched more easily than the dielectric layer 22, and so the covering member 40 is not affected much in the step of polishing the upper surface 22a of the dielectric layer 22. Therefore, the step of causing the upper surface 22a of the dielectric layer 22 to approach flat can be stably performed.

According to the embodiment, by performing the step of causing the upper surface 22a of the dielectric layer 22 to approach flat after forming the trench 17, foreign matter generated by patterning the resin member 18, the covering member 40, etc., can be prevented from adhering to the upper surface 22a. Because direct bonding can be performed with little foreign matter on the upper surface 22a, the dielectric layer 22 and the wavelength conversion member 23 can be bonded with a higher bonding strength.

According to the embodiments above, a method for manufacturing a light-emitting device can be realized in which a wavelength conversion member is bonded with a high bonding strength to a dielectric layer located at an upper surface of a semiconductor part.

Although several embodiments of the invention are described hereinabove, these embodiments have been presented by way of example only, and are not intended to limit the scope of the inventions. These novel embodiments may be embodied in a variety of other forms, and various omissions, substitutions, and changes may be made without departing from the spirit of the inventions. Such embodiments and their modifications are within the scope and spirit of the inventions, and are within the scope of the inventions described in the claims and their equivalents. The embodiments above can be implemented in combination with each other.

What is claimed is:

1. A method for manufacturing a light-emitting device, the method comprising:
providing a wafer comprising:
a first substrate including a first surface, and
a plurality of semiconductor parts arranged on the first surface, the plurality of semiconductor parts being separated from each other, each of the plurality of semiconductor parts comprising a light-emitting part;
disposing a resin member covering the plurality of semiconductor parts and the first surface positioned between the plurality of semiconductor parts;
disposing a second substrate on the resin member;
exposing portions of the plurality of semiconductor parts and a portion of the resin member by removing the first substrate;
forming a dielectric layer continuously covering the portions of the plurality of semiconductor parts and the portion of the resin member;
causing an upper surface of the dielectric layer to approach flat;
selectively removing the dielectric layer located on the portion of the resin member; and
directly bonding a wavelength conversion member to the upper surface of the dielectric layer that has been caused to approach flat, the wavelength conversion member covering the plurality of semiconductor parts.

2. The method according to claim 1, wherein:
the step of selectively removing the dielectric layer located on the portion of the resin member is performed after the step of causing the upper surface of the dielectric layer to approach flat.

3. The method according to claim 2, wherein:
the step of causing the upper surface of the dielectric layer to approach flat comprises performing chemical mechanical polishing of the dielectric layer, and
in the step of performing chemical mechanical polishing of the dielectric layer, an etching rate of the resin member is less than an etching rate of the dielectric layer.

4. The method according to claim 1, wherein:
the step of causing the upper surface of the dielectric layer to approach flat is performed after the step of selectively removing the dielectric layer located on the portion of the upper surface of the resin member.

5. The method according to claim 4, wherein:
the step of selectively removing the dielectric layer located on the portion of the upper surface of the resin member comprises continuously removing the resin member exposed after selectively removing the dielectric layer,
the method further comprises forming a covering member covering the dielectric layer and the portion at which the resin member is removed,
the step of causing the upper surface of the dielectric layer to approach flat comprises performing chemical mechanical polishing of the dielectric layer and the covering member, and
in the chemical mechanical polishing of the dielectric layer and the covering member, an etching rate of the covering member is greater than an etching rate of the dielectric layer.

6. The method according to claim 1, wherein:
the step of selectively removing the dielectric layer located on the portion of the resin member comprises continuously removing the resin member exposed after selectively removing the dielectric layer.

7. The method according to claim 2, wherein:
the step of selectively removing the dielectric layer located on the portion of the resin member comprises continuously removing the resin member exposed after selectively removing the dielectric layer.

8. The method according to claim 3, wherein:
the step of selectively removing the dielectric layer located on the portion of the resin member comprises continuously removing the resin member exposed after selectively removing the dielectric layer.

9. The method according to claim 1, further comprising:
after the step of exposing the portions of the plurality of semiconductor parts and the portion of the resin member, roughening the exposed portions of the plurality of semiconductor parts.

10. The method according to claim 3, further comprising:
after the step of exposing the portions of the plurality of semiconductor parts and the portion of the resin member, roughening the exposed portions of the plurality of semiconductor parts.

11. The method according to claim 4, further comprising:
after the step of exposing the portions of the plurality of semiconductor parts and the portion of the resin member, roughening the exposed portions of the plurality of semiconductor parts.

12. The method according to claim 1, further comprising:
after the step of directly bonding the wavelength conversion member, cleaving the wavelength conversion member positioned between the plurality of semiconductor parts.

13. The method according to claim 3, further comprising:
after the step of directly bonding the wavelength conversion member, cleaving the wavelength conversion member positioned between the plurality of semiconductor parts.

14. The method according to claim 4, further comprising:
after the step of directly bonding the wavelength conversion member, cleaving the wavelength conversion member positioned between the plurality of semiconductor parts.
